(19) United States
(12) Patent Application Publication
(10) Pub. No.: US 2020/0191647 A1
(43) Pub. Date: Jun. 18, 2020

(54) HIGH-SPEED TRAIN GEARBOX SENSING DEVICE

(71) Applicant: FATRI United Testing & Control (Quanzhou) Technologies Co., Ltd., Quanzhou City (CN)

(72) Inventors: Nie Yongzhong, Quanzhou City (CN); Luo Chengxu, Quanzhou City (CN)

(21) Appl. No.: 16/575,511

(22) Filed: Sep. 19, 2019

(30) Foreign Application Priority Data
Dec. 17, 2018 (CN) 201822118577.9

(51) Int. Cl. G01H 11/08; H05K 9/00; B61K 9/02; F16H 57/01; G01K 7/18; G01M 13/028

(52) U.S. Cl. CPC G01H 11/08; H05K 9/0007; G01M 13/028; F16H 57/01; G01K 7/18; B61K 9/02

(57) ABSTRACT

The present application provides a high-speed train gearbox sensing device, comprising: a housing, disposed on the high-speed train gearbox; a piezoelectric sensor, fixedly disposed in the housing, and with vibration of the high-speed gearbox, converting mechanical energy generated by the vibration into electric energy using piezoelectric effect, and transmitting a signal to a central control system; a shielding case, disposed outside the piezoelectric sensor for shielding electromagnetic interference from the piezoelectric sensor. The above sensing device is installed to the high-speed train gearbox, for collecting vibration information using the piezoelectric sensor, so as to enable monitoring of gearbox vibration. In order to ensure the normal operation of the sensor, the design with high-pressure resistance and anti-electromagnetic interference in structure is adopted to prolong the service life of the sensor, so as to achieve the purpose of real-time online monitoring whether the gearbox is in a good state.

### CROSS REFERENCE TO RELATED APPLICATIONS

This application claims priority to Chinese Patent Application No. 2018221185779, filed on Dec. 17, 2018, the entire contents of which are incorporated herein by reference.

### TECHNICAL FIELD

The present application refers to the field of sensing device, in particular to a high-speed train gearbox sensing device.

### BACKGROUND

A high-speed train gearbox is a key device for high-speed train power transmission. It is one of top ten supporting technologies for high-speed EMU and one of the most important transmission links in the EMU transmission system. The requirements for the accuracy and reliability of high-speed train gearbox are high, and whether the high-speed train gearbox is in a good state has a great effect on driving safety.

During the fault diagnosis of gearbox, there is a lot of information, such as the vibration signal that can quickly and directly reflect the operating state of the gearbox, used for detection and diagnosis. According to statistics, most of faults will be manifested in the form of vibration. At the same time, the temperature field of the gearbox constantly changes as the train speed increases and the operating environment changes constantly. The operation of the gearbox may be adversely affected by too high or too low temperatures.

However, in the prior art, the high-speed train gearbox does not have the function of feeding back the vibration of the gearbox in real time, and thus the safety hazard cannot be found in time through the performance of the gearbox, thereby avoiding the occurrence of dangerous accidents.

### SUMMARY

Therefore, in order to overcome the problem that the high-speed train gearbox in prior art may not feedback the vibration inside the gearbox in real time, thereby providing a high-speed train gearbox sensing device that may feedback the vibration inside the gearbox in real time and avoid the occurrence of accidents.

The technical solution of the present application is as follows.

A high-speed train gearbox sensing device comprises: a housing, disposed on the high-speed train gearbox; a piezoelectric sensor, fixedly disposed in the housing, and with vibration of the high-speed gearbox, converting mechanical energy generated by the vibration into electric energy using piezoelectric effect, and transmitting a signal to a central control system; a shielding case, disposed outside the piezoelectric sensor for shielding electromagnetic interference from the piezoelectric sensor.

Preferably, the high-speed train gearbox sensing device further comprises a circuit board disposed in the shielding case; the circuit board is connected with the piezoelectric sensor for processing signals of the piezoelectric sensor; the shielding case comprises an upper layer for shielding electromagnetic interference of the housing from the circuit board and a lower layer for protecting and supporting the circuit board.

Preferably, the housing and the shielding case have a pouring sealant filled there between, for fixing and insulating the shielding case.

Preferably, the housing has an insulating spacer disposed at a bottom thereof, and the shielding case is disposed above the insulating spacer.

Preferably, the piezoelectric sensor is a piezoelectric ceramic.

Preferably, the high-speed train gearbox sensing device further comprises a balancing weight fixedly coupled to the piezoelectric ceramic and vibrating in synchronization with the piezoelectric ceramic, for amplifying the signal intensity generated by the piezoelectric effect.

Preferably, a temperature sensor is further provided on an exterior of the housing.

Preferably, the temperature sensor is a temperature probe extending into the high-speed train gearbox.

Preferably, the temperature probe comprises a casing provided with a Pt100 platinum thermal resistor, which is connected to the central control system.

Preferably, the casing is filled with a thermal conductive paste.

The technical solution of the present application has the following advantages.

1. A high-speed train gearbox sensing device provided by the present application comprises: a housing, disposed on the high-speed train gearbox; a piezoelectric sensor, fixedly disposed in the housing, and with vibration of the high-speed gearbox, converting mechanical energy generated by the vibration into electric energy using piezoelectric effect, and transmitting a signal to a central control system; a shielding case, disposed outside the piezoelectric sensor for shielding electromagnetic interference from the piezoelectric sensor. The above sensing device is installed to the high-speed train gearbox, for collecting vibration information using the piezoelectric sensor, so as to enable monitoring of gearbox vibration. At the same time, in order to ensure the normal operation of the sensor, the design with high-pressure resistance and anti-electromagnetic interference in structure is adopted to prolong the service life of the sensor, so as to achieve the purpose of real-time online monitoring whether the gearbox is in a good state.

2. The high-speed train gearbox sensing device provided by the present application further comprises a circuit board disposed in the shielding case; the circuit board is connected with the piezoelectric sensor for processing signals of the piezoelectric sensor; the shielding case comprises an upper layer for shielding electromagnetic interference of the housing from the circuit board and a lower layer for protecting and supporting the circuit board. The housing and the shielding case have a pouring sealant filled there between, for fixing and insulating the shielding case. The housing has an insulating spacer disposed at a bottom thereof, and the shielding case is disposed above the insulating spacer. The piezoelectric sensor is isolated and insulated from the housing by the insulating spacer, shielding case, and pouring sealant, so that the piezoelectric sensor may meet requirements of high pressure resistance with AC2500V/Hz and 1 min.

3. In the high-speed train gearbox sensing device provided by the present application, a temperature sensor is further provided on an exterior of the housing. The temperature sensor is a temperature probe extending into the high-speed train gearbox. Two sets of Pt100 platinum resistance elements are placed in the probe, which is then injected the high-temperature resistant thermal conductive paste therein to complete encapsulation. Operating temperature of the gearbox may be sensed in real time through subsequent data processing, i.e. using the indexing characteristic table of the platinum resistance. The shielding case, an insulating sheet, and the pouring sealant are used to isolate and insulate a core subassembly of the piezoelectric sensor from an external structure, through the temperature probe combined with the piezoelectric accelerometer, so as to design a high voltage resistance vibration and temperature integrated sensor structure capable of simultaneously monitoring vibration state and temperature state of the gear box. Through a reasonable structure layout, i.e. the temperature sensor adopts a probe type structure, and the acceleration sensor adopts a square sealing structure, the two sensors are arranged separately to meet their respective operating temperature ranges, reducing the temperature resistance requirements of the piezoelectric acceleration sensor, so that the two sensors have good independence and strong anti-interference ability, which improves the precision of signal acquisition.

### BRIEF DESCRIPTION OF THE DRAWING

One or more embodiments are illustrated by way of example, and not by limitation, in the figures of the accompanying drawings, wherein elements having the same reference numeral designations represent like elements throughout. The drawings are not to scale, unless otherwise disclosed.

In order to more clearly illustrate the technical solutions of the embodiments of the present application or the prior art, the drawings used in the embodiments of the present application or the prior art will be briefly described below. Obviously, the drawings in the following description are only some embodiments of the present application, and those skilled in the art can obtain other drawings based on these drawings without any creative efforts.

FIG. 1 is a schematic view showing a structure of a high-speed train gearbox sensing device of the present application;

FIG. 2 is a schematic view showing an internal structure of a piezoelectric sensor of the present application;

FIG. 3 is a schematic view showing an internal structure of a temperature sensor of the present application

In the drawings, the reference numerals are:

1—shielding case; 2—circuit board; 3—pouring sealant; 4—insulating spacer; 5—piezoelectric ceramic; 6—balancing weight; 7—temperature probe; 8—platinum thermal resistor; 9—thermal conductive paste; 10—housing.

### DETAILED DESCRIPTION

The technical solutions of the present application will be described clearly and completely with reference to the accompanying drawings. It is obvious that the described embodiments are only a part of the embodiments of the present application, and not all of the embodiments. All other embodiments obtained by those skilled in the art based on the embodiments of the present application without any creative efforts are within the scope of the present application.

In the description of the present application, it should be noted that the orientation or positional relationship indicative of the terms such as “center”, “upper”, “lower”, “left”, “right”, “vertical”, “horizontal”, “inside”, “outside” is the orientation or positional relationship shown in the drawings, which is merely for the convenience of the description and the simplified description of the present application, and is not intended to indicate or imply that the device or component referred to has a specific orientation and is constructed and operated in a specific orientation. Therefore, it should not be construed as a limitation of the present application. Moreover, the terms “first,” “second,” and “third” are used for descriptive purposes only and are not to be construed as indicating or implying relative importance.

In the description of the present application, it should be noted that the terms “installed”, “linked”, and “connected” are to be understood broadly, unless otherwise clearly stipulated and defined, and may be, for example, fixedly connected, detachably connected, or integrally connected; mechanically connected or electrically connected; directly connected or indirectly connected through an intermediate medium, and may be internal communication between the two elements. The specific meanings of the above terms in the present application may be understood by those skilled in the art based on a particular case.

Further, the technical features involved in the different embodiments of the present application described below may be combined with each other as long as they do not constitute a conflict with each other.

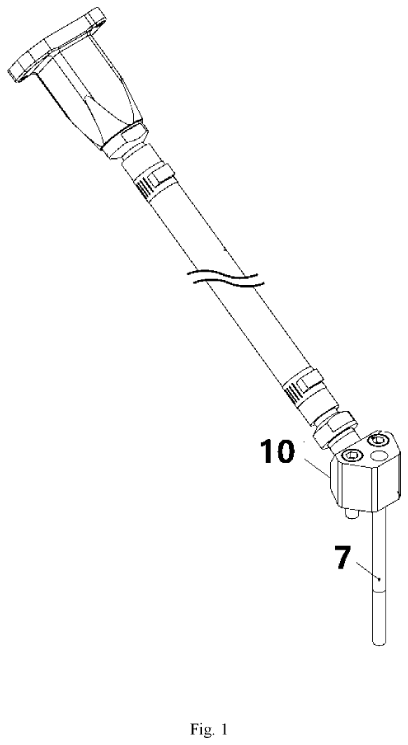

A high-speed train gearbox sensing device provided by the present application, as shown in FIG. 1, comprises a housing 10, a piezoelectric sensor, a shielding case 1, and a temperature sensor.

The housing 10 is disposed on the high-speed train gearbox. The piezoelectric sensor is fixedly disposed in the housing 10, and with vibration of the high-speed gearbox, converting mechanical energy generated by the vibration into electric energy using piezoelectric effect, and transmitting a signal to a central control system. The piezoelectric sensor is a piezoelectric ceramic 5. The high-speed train gearbox sensing device further comprises a balancing weight 6 fixedly coupled to the piezoelectric ceramic 5 and vibrating in synchronization with the piezoelectric ceramic 5, for amplifying the signal intensity generated by the piezoelectric effect. The above sensing device is installed to the high-speed train gearbox, for collecting vibration information using the piezoelectric sensor, so as to enable monitoring of gearbox vibration. At the same time, in order to ensure the normal operation of the sensor, the design with high-pressure resistance and anti-electromagnetic interference in structure is adopted to prolong the service life of the sensor, so as to achieve the purpose of real-time online monitoring whether the gearbox is in a good state.

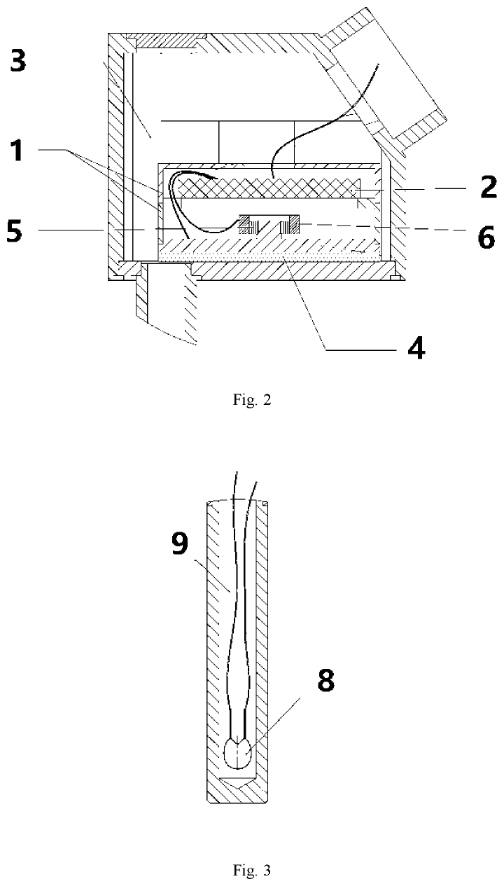

As shown in FIG. 2, the shielding case 1 is disposed outside the piezoelectric sensor for shielding electromagnetic interference from the piezoelectric sensor. A circuit board 2 is disposed in the shielding case 1; the circuit board 2 is connected with the piezoelectric sensor for processing signals of the piezoelectric sensor; the shielding case 1 comprises an upper layer for shielding electromagnetic interference of the housing 10 from the circuit board 2 and a lower layer for protecting and supporting the circuit board 2. The housing 10 and the shielding case 1 have a pouring sealant 3 filled there between, for fixing and insulating the shielding case 1. The housing 10 has an insulating spacer 4 disposed at a bottom thereof, and the shielding case 1 is disposed above the insulating spacer 4. The piezoelectric sensor is isolated and insulated from the housing 10 by the insulating spacer 4, shielding case 1, and pouring sealant 3, so that the piezoelectric sensor may meet requirements of high pressure resistance with AC2500V/Hz and 1 min.

As shown in FIG. 3, a temperature sensor is further provided on an exterior of the housing 10. The temperature sensor is a temperature probe 7 extending into the high-speed train gearbox. The temperature probe 7 comprises a casing provided with a Pt100 platinum thermal resistor 8, which is connected to the central control system. The casing is filled with a thermal conductive paste 9. Two sets of Pt100 platinum resistance elements are placed in the probe, which is then injected the high-temperature resistant thermal conductive paste 9 therein to complete encapsulation. Operating temperature of the gearbox may be sensed in real time through subsequent data processing, i.e. using the indexing characteristic table of the platinum resistance. The shielding case 1, an insulating sheet, and the pouring sealant 3 are used to isolate and insulate a core subassembly of the piezoelectric sensor from an external structure, through the temperature probe 7 combined with the piezoelectric accelerometer, so as to design a high voltage resistance vibration and temperature integrated sensor structure capable of simultaneously monitoring vibration state and temperature state of the gear box. Through a reasonable structure layout, i.e. the temperature sensor adopts a probe type structure, and the acceleration sensor adopts a square sealing structure, the two sensors are arranged separately to meet their respective operating temperature ranges, reducing the temperature resistance requirement of the piezoelectric acceleration sensor, so that the two sensors have good independence and strong anti-interference ability, which improves the precision of signal acquisition.

It is apparent that the above embodiments are merely examples for clarity of illustration, and are not intended to limit the embodiments. Other variations or modifications of the various forms may be made by those skilled in the art in view of the above description. There is no need and no way to present all of the embodiments. The obvious variations or modifications derived therefrom are still within the scope of protection created by the present application.

What is claimed is:

1. A high-speed train gearbox sensing device, comprising:
a housing, disposed on the high-speed train gearbox;
a piezoelectric sensor, fixedly disposed in the housing, and with vibration of the high-speed gearbox, converting mechanical energy generated by the vibration into electric energy using piezoelectric effect, and transmitting a signal to a central control system;
a shielding case, disposed outside the piezoelectric sensor for shielding electromagnetic interference from the piezoelectric sensor.

2. The high-speed train gearbox sensing device according to claim 1, further comprising a circuit board disposed in the shielding case; the circuit board is connected with the piezoelectric sensor for processing signals of the piezoelectric sensor; the shielding case comprises an upper layer for shielding electromagnetic interference of the housing from the circuit board and a lower layer for protecting and supporting the circuit board.

3. The high-speed train gearbox sensing device according to claim 2, wherein the housing and the shielding case have a pouring sealant filled there between, for fixing and insulating the shielding case.

4. The high-speed train gearbox sensing device according to claim 3, wherein, the housing has an insulating spacer disposed at a bottom thereof, and the shielding case is disposed above the insulating spacer.

5. The high-speed train gearbox sensing device according to claim 1, wherein, the piezoelectric sensor is a piezoelectric ceramic.

6. The high-speed train gearbox sensing device according to claim 5, further comprising a balancing weight fixedly coupled to the piezoelectric ceramic and vibrating in synchronization with the piezoelectric ceramic, for amplifying the signal intensity generated by the piezoelectric effect.

7. The high-speed train gearbox sensing device according to claim 1, wherein a temperature sensor is further provided on an exterior of the housing.

8. The high-speed train gearbox sensing device according to claim 7, wherein, the temperature sensor is a temperature probe extending into the high-speed train gearbox.

9. The high-speed train gearbox sensing device according to claim 8, wherein the temperature probe comprises a casing provided with a Pt100 platinum thermal resistor, which is connected to the central control system.

10. The high-speed train gearbox sensing device according to claim 9, wherein the casing is filled with a thermal conductive paste.

11. The high-speed train gearbox sensing device according to claim 2, wherein a temperature sensor is further provided on an exterior of the housing.

12. The high-speed train gearbox sensing device according to claim 3, wherein a temperature sensor is further provided on an exterior of the housing.

13. The high-speed train gearbox sensing device according to claim 4, wherein a temperature sensor is further provided on an exterior of the housing.

14. The high-speed train gearbox sensing device according to claim 5, wherein a temperature sensor is further provided on an exterior of the housing.

15. The high-speed train gearbox sensing device according to claim 6, wherein a temperature sensor is further provided on an exterior of the housing.
